(19) United States
(12) Patent Application Publication
(10) Pub. No.: US 2020/0240008 A1
(43) Pub. Date: Jul. 30, 2020

(54) APPARATUS FOR VACUUM PROCESSING OF A SUBSTRATE, SYSTEM FOR THE MANUFACTURE OF DEVICES HAVING ORGANIC MATERIALS, AND METHOD FOR SEALING A PROCESSING VACUUM CHAMBER AND A MAINTENANCE VACUUM CHAMBER FROM EACH OTHER

(71) Applicants: Sebastian Gunther ZANG, Grossostheim (DE); Andreas SAUER, Großostheim (DE); Applied Materials, Inc., Santa Clara, CA (US)

(72) Inventors: Sebastian Gunther ZANG, Mainaschaff (DE); Andreas SAUER, Großostheim (DE)

(21) Appl. No.: 15/759,801

(22) PCT Filed: Mar. 17, 2017
(86) PCT No.: PCT/EP2017/056372

§ 371 Date: Mar. 13, 2018

(51) Int. Cl. C23C 14/56; C23C 14/24; F16K 51/02

(52) U.S. Cl. CPC C23C 14/56; C23C 14/243; H01L 51/56; F16K 51/02; C23C 14/246

(57) ABSTRACT

The present disclosure provides an apparatus for vacuum processing of a substrate. The apparatus includes a processing vacuum chamber, a maintenance vacuum chamber, an opening for transferring at least a portion of a material deposition source between the processing vacuum chamber and the maintenance vacuum chamber, and a magnetic closing arrangement for magnetically closing the opening.

### FIELD

Embodiments of the present disclosure relate to an apparatus for vacuum processing of a substrate, a system for the manufacture of devices having organic materials, and a method for sealing a processing vacuum chamber and a maintenance vacuum chamber from each other. Embodiments of the present disclosure particularly relate to apparatuses, systems and methods used in the manufacture of organic light-emitting diode (OLED) devices.

### BACKGROUND

Techniques for layer deposition on a substrate include, for example, thermal evaporation, physical vapor deposition (PVD), and chemical vapor deposition (CVD). Coated substrates may be used in several applications and in several technical fields. For instance, coated substrates may be used in the field of organic light emitting diode (OLED) devices. OLEDs can be used in the manufacture of television screens, computer monitors, mobile phones, other hand-held devices, and the like for displaying information. An OLED device, such as an OLED display, may include one or more layers of an organic material situated between two electrodes that are all deposited on a substrate.

OLED devices can include a stack of several organic materials, which are for example evaporated in a vacuum chamber of a processing apparatus. The organic materials are deposited on a substrate in a subsequent manner through shadow masks using evaporation sources. The substrate, the shadow masks and the evaporation sources are provided within the vacuum chamber. The evaporation sources have to be serviced and refilled from time to time. For servicing and refilling evaporation sources, the processing apparatus has to be shut down, the vacuum chamber has to be vented, and the evaporation source has to be removed from the vacuum chamber. In view of this, servicing and refilling evaporation sources causes a considerable workload and is time consuming, leading to an increased downtime of the processing apparatus and a reduced processing efficiency or throughput.

Therefore, there is a need for apparatuses, system and methods, which facilitate the servicing and refilling of material deposition sources, such as evaporations sources, and reduce a downtime of the processing apparatus.

### SUMMARY

In light of the above, an apparatus for vacuum processing of a substrate, a system for the manufacture of devices having organic materials, and a method for sealing a processing vacuum chamber and a maintenance vacuum chamber from each other are provided. Further aspects, benefits, and features of the present disclosure are apparent from the claims, the description, and the accompanying drawings.

According to an aspect of the present disclosure, an apparatus for vacuum processing of a substrate is provided. The apparatus includes a processing vacuum chamber, a maintenance vacuum chamber, an opening for transferring at least a portion of a material deposition source between the processing vacuum chamber and the maintenance vacuum chamber, and a magnetic closing arrangement for magnetically closing the opening.

According to another aspect of the present disclosure, a system for the manufacture of devices having organic materials is provided. The system includes the apparatus for vacuum processing of a substrate according to the embodiments described herein, and a transport arrangement configured for contactless transportation of at least one of a substrate carrier and a mask carrier in the processing vacuum chamber.

According to a further aspect of the present disclosure, a method for sealing a processing vacuum chamber and a maintenance vacuum chamber from each other is provided. The method includes holding a sealing device at an opening using a magnetic force.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIGS. 1A and B show schematic top views of an apparatus for vacuum processing of a substrate according to embodiments described herein;

FIG. 1C shows a schematic top view of an apparatus for vacuum processing of a substrate according to further embodiments described herein;

FIG. 2 shows a schematic sequence of closing the opening of the apparatus with a sealing device according to embodiments described herein;

FIGS. 3A and 3B show schematic views of a magnetic closing arrangement in a releasing state and a chucking state, respectively, according to embodiments described herein;

FIGS. 4A to 4C show schematic top views of an apparatus for vacuum processing of a substrate according to yet further embodiments described herein;

FIG. 5 shows a schematic perspective view of an apparatus for vacuum processing of a substrate according to other embodiments described herein; and

FIG. 6 shows a flowchart of a method for sealing a processing vacuum chamber and a maintenance vacuum chamber from each other according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

The embodiments disclosed herein facilitate servicing and/or refilling of material deposition sources, such as evaporation sources, and can reduce a downtime of the processing apparatus. In particular, the maintenance vacuum chamber is connected to the processing vacuum chamber such that at least a portion of the material deposition source can be transferred from the processing vacuum chamber to the maintenance vacuum chamber, and vice versa, via a sealable opening. The maintenance vacuum chamber can be vented independently from the processing vacuum chamber. The material deposition source can be exchanged, e.g., after the material deposition source is exhausted, and/or serviced in the maintenance vacuum chamber without venting the vacuum system and/or without stopping production.

The sealable opening is closable using a magnetic closing arrangement. For example, a sealing device, such as a service flange, can cover the opening and can be magnetically held at the opening to seal the opening. The magnetic sealing can reduce a number of mechanically movable parts in the vacuum system. A generation of particles due to such mechanically movable parts can be reduced and a quality of the material layers deposited on the substrate can be improved.

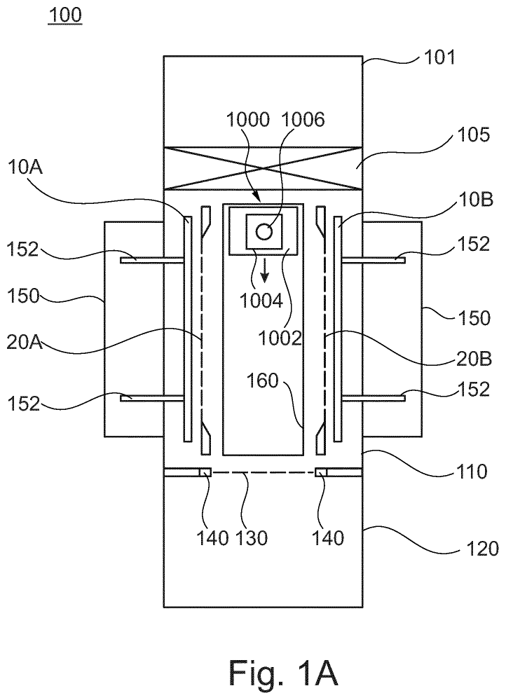

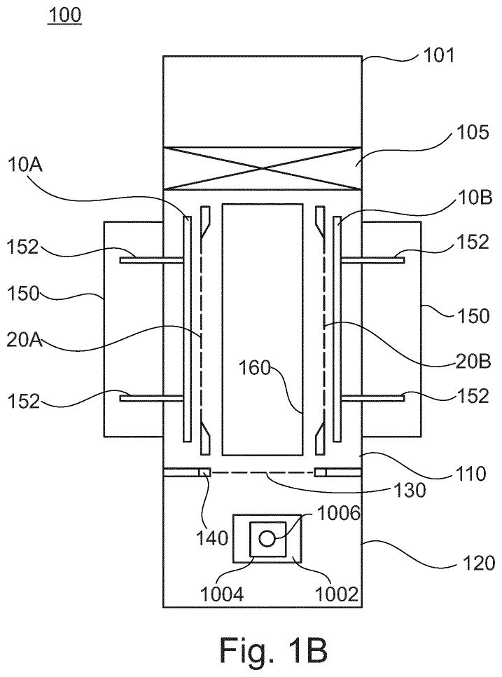

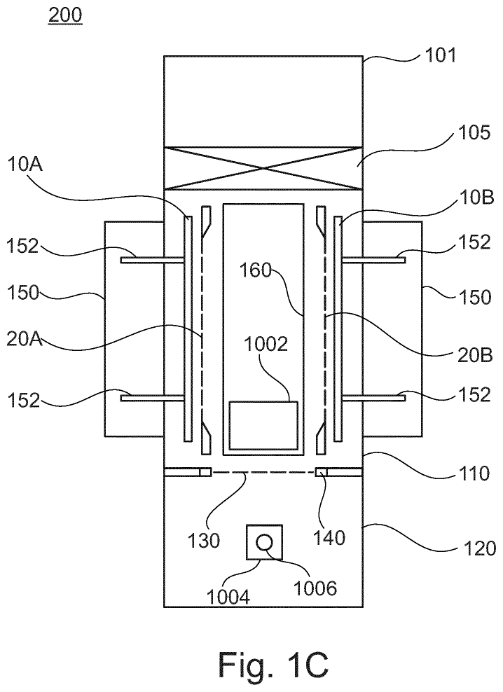

FIGS. 1A and B show schematic top views of an apparatus 100 for vacuum processing of a substrate according to embodiments described herein. The apparatus 100 can be configured for deposition of layers of an organic material on a substrate, for example, to manufacture OLED devices.

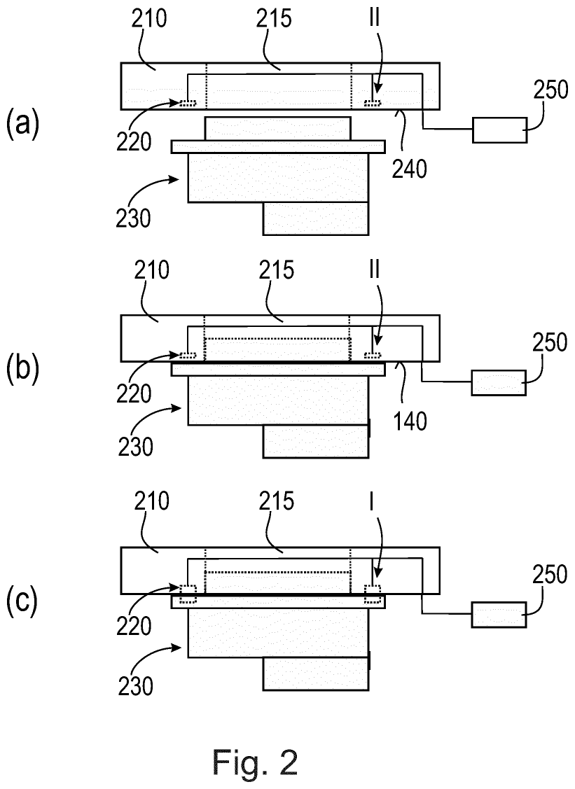

The apparatus 100 includes a processing vacuum chamber 110, a maintenance vacuum chamber 120, an opening 130 for transferring at least a portion of a material deposition source between the processing vacuum chamber 110 and the maintenance vacuum chamber 120, and a magnetic closing arrangement 140 for magnetically closing the opening 130. The magnetic closing arrangement 140 can be provided at the opening 130. The apparatus 100 can further include a sealing device, such as a service flange, configured for closing the opening 130. An exemplary sealing device is explained with respect to FIG. 2.

According to some embodiments, which can be combined with other embodiments herein, the material deposition source can be an evaporation source 1000 e.g. for organic material. The evaporation source 1000 may include an evaporation crucible 1004, a distribution pipe 1006, and optionally a support 1002 for the distribution pipe 1006. The evaporation crucible 1004 can be configured to evaporate the organic material for deposition on the substrate. The distribution pipe 1006 can have one or more outlets and can be in fluid communication with the evaporation crucible 1004. In some implementations, the distribution pipe 1006 is rotatable around an axis during evaporation.

FIGS. 1A and B show the apparatus 100 with the evaporation source 1000 being at different positions. In FIG. 1A, the evaporation source 1000 is positioned in the processing vacuum chamber 110, and in FIG. 1B the evaporation source 1000 is positioned in the maintenance vacuum chamber 120, e.g., for servicing and/or refilling. Although FIGS. 1A and B illustrate one evaporation source, in some examples two or more evaporation sources can be provided in the apparatus 100. As an example, a first evaporation source can be positioned in the processing vacuum chamber 110, and a second evaporation source can be positioned in the maintenance vacuum chamber 120. The first evaporation source can be operated for manufacturing devices, particularly devices including organic materials therein, while the second evaporation source positioned in the maintenance vacuum chamber 120 can be simultaneously serviced and/or refilled. A downtime of the apparatus 100 can be further reduced or even avoided.

According to some embodiments, which can be combined with other embodiments described herein, the apparatus 100 includes a transfer device (not shown) configured for transferring the material deposition source, such as the evaporation source 1000, from the processing vacuum chamber 110 to the maintenance vacuum chamber 120 and from the maintenance vacuum chamber 120 to the processing vacuum chamber 110. The transfer device can include a displacement device, such as an actuator, a drive, or an arm, connectable to the material deposition source for performing the transfer.

The evaporation source 1000 can include one or more evaporation crucibles 1004 adapted to contain the evaporation material, and one or more distribution pipes 1006. According to some embodiments, which can be combined with other embodiments described herein, the apparatus 100, and particularly the evaporation source 1000, includes the support 1002 for the distribution pipe 1006. The distribution pipe 1006 can be supported by the support 1002. Further, according to some embodiments, the one or more evaporation crucibles 1004 can also be supported by the support 1002. In some implementations, the evaporation source 1000 is configured for a rotation around an axis, particularly during evaporation. In some implementations, the distribution pipe 1006 is a vapor distribution showerhead, particularly a linear vapor distribution showerhead. The distribution pipe 1006 may provide a line source extending essentially vertically.

In some embodiments, a surface of the substrate is coated using the evaporation source 1000 extending in one direction corresponding to one substrate dimension and a translational movement (indicated by the arrow in FIG. 1A) along the other direction corresponding to the other substrate dimension. Vapor generated in the evaporation crucible 1004 can move upwardly and out of one or more outlets of the distribution pipe 1006. The one or more outlets of the distribution pipe 1006 can be one or more openings or one or more nozzles, which can, e.g., be provided in a showerhead or another vapor distribution system. The evaporation source 1000 can include a vapor distribution showerhead, e.g. a linear vapor distribution showerhead having a plurality of nozzles or openings. A showerhead as understood herein can include an enclosure having openings such that the pressure in the showerhead is higher than that outside of the showerhead, for example by at least one order of magnitude.

In some implementations, a mask, such as an edge exclusion mask or a shadow mask, can be provided for masking the substrate during a layer deposition process. The term “masking” may include reducing and/or hindering a deposition of material on one or more regions of the substrate. The masking may be useful, for instance, in order to define the area to be coated. In some applications, only parts of the substrate are coated and the parts not to be coated are covered by the mask.

According to some embodiments, which can be combined with any other embodiment described herein, the substrate can be supported by a substrate carrier, such as an electrostatic chuck. The mask can be supported by a mask carrier. In FIG. 1A, two substrates, e.g. a first substrate 10A and a second substrate 10B, and two masks, e.g., a first mask 20A and a second mask 20B, are exemplarily shown. The substrate carrier(s) supporting the substrate(s) can be supported on respective first transport arrangements, such as one or more first tracks, configured for transportation of the substrate carrier(s). The mask carriers supporting the masks can be supported on respective second transport arrangements, such as one or more second tracks, configured for transportation of the mask carrier(s).

According to some embodiments, which can be combined with other embodiments described herein, a transport arrangement configured for contactless levitation and/or contactless transportation of the substrate carrier and/or the mask carrier can be provided. In particular, the first transport arrangement can be configured for contactless levitation and/or contactless transportation of the substrate carrier. Likewise, the second transport arrangement can be configured for contactless levitation and/or contactless transportation of the mask carrier. As an example, a system for the manufacture of devices having organic materials can include the apparatus of the present disclosure and the transport arrangement configured for contactless transportation of at least one of the substrate carrier and the mask carrier in the processing vacuum chamber. In some implementations, the transport arrangement can be included in the apparatus.

In some embodiments, the transport arrangement can include a guiding structure configured for contactless levitation of the substrate carrier and/or the mask carrier. Likewise, the transport arrangement can include a drive structure configured for contactless transportation of the substrate carrier and/or the mask carrier.

In the present disclosure, a track or track arrangement configured for contactless transportation is to be understood as a track or track arrangement which is configured for contactless transportation of a carrier, particularly a substrate carrier or a mask carrier. The term “contactless” can be understood in the sense that the weight of the carrier, e.g. of the substrate carrier or mask carrier, is not held by a mechanical contact or mechanical forces, but is held by a magnetic force. In particular, the carrier can be held in a levitating or floating state using magnetic forces instead of mechanical forces. For example, in some implementations, there can be no mechanical contact between the carrier and the transportation track, particularly during levitation, movement and positioning of the substrate carrier and/or mask carrier.

The contactless levitation and/or transportation of the carrier(s) is beneficial in that no particles are generated during transportation, for example due to mechanical contact with guide rails. An improved purity and uniformity of the layers deposited on the substrate can be provided, since particle generation is minimized when using the contactless levitation and/or transportation.

According to some embodiments, which can be combined with other embodiments described herein, the substrate is supported by the substrate carrier, which can be connected to an alignment system 150, e.g., by connecting elements 152. The alignment system 150 can be configured for adjusting the position of the substrate with respect to the mask. It is to be understood that the substrate can be moved relative to the mask in order to provide for a proper alignment between the substrate and the mask during deposition of the organic material. According to a further embodiment, which can be combined with other embodiments described herein, alternatively or additionally the mask carrier holding the mask can be connected to the alignment system 150. Accordingly, either the mask can be positioned relative to the substrate or the mask and the substrate can both be positioned relative to each other. An alignment system as described herein may allow for a proper alignment of the masking during the deposition process, which is beneficial for high quality or OLED display manufacturing.

Examples of an alignment of a mask and a substrate relative to each other include alignment units that allow for a relative alignment in at least two directions defining a plane, which is essentially parallel to the plane of the substrate and the plane of the mask. For example, an alignment can at least be conducted in an x-direction and a y-direction, i.e. two Cartesian directions defining the above-described parallel plane. Typically, the mask and the substrate can be essentially parallel to each other. Specifically, the alignment can further be conducted in a direction essentially perpendicular to the plane of the substrate and the plane of the mask. Thus, an alignment unit is configured at least for an X-Y-alignment, and specifically for an X-Y-Z-alignment of the mask and the substrate relative to each other. One specific example, which can be combined with other embodiments described herein, is to align the substrate in the x-direction, y-direction and z-direction to a mask, which can be held stationary in the vacuum processing chamber.

According to some embodiments, which can be combined with other embodiments described herein, the material deposition source, such as the evaporation source 1000, is configured for a translational movement, in particular within the processing vacuum chamber 110. As an example, the apparatus 100 includes a source drive configured for the translational movement of the evaporation source 1000. In some embodiments, the source drive is connectable to the evaporation source 1000 or is included in the evaporation source 1000. According to some embodiments, the support 1002 is connectable to the source drive or includes the source drive. The source drive can be a motor or another suitable actuator.

According to some embodiments, which can be combined with other embodiments described herein, the apparatus 100 further includes a source support system disposed in the processing vacuum chamber 110 and having at least two tracks 160, wherein the at least two tracks 160 of the source support system are configured for the translational movement of the material deposition source at least within the processing vacuum chamber 110. As an example, the source drive can be configured to move or transfer the material deposition source along the at least two tracks 160.

In some implementations, the evaporation source 1000 is provided in the processing vacuum chamber 110 on the at least two tracks 160, e.g. a looped track or linear guide. The at least two tracks 160 are configured for the translational movement of the material deposition source, in particular during operation, such as a deposition process. According to some embodiments, which can be combined with other embodiments described herein, the source drive for the translational movement of the material deposition source can be provided at the at least two tracks 160, in the material deposition source, within the processing vacuum chamber 110, or a combination thereof.

According to some embodiments, which can be combined with other embodiments described herein, the apparatus 100 includes at least one further vacuum chamber 101 connected to the processing vacuum chamber 110 e.g. via a valve 105. The at least one further vacuum chamber 101 can be configured for a transport of the substrate into the processing vacuum chamber 110 and out of the processing vacuum chamber 110. FIGS. 1A to 1C show the valve 105, for example a gate valve. The valve 105 allows for a vacuum seal between the processing vacuum chamber 110 and the at least one further vacuum chamber 101. The valve 105 can be opened for transport of the substrate and/or the mask into the processing vacuum chamber 110 or out of the processing vacuum chamber 110.

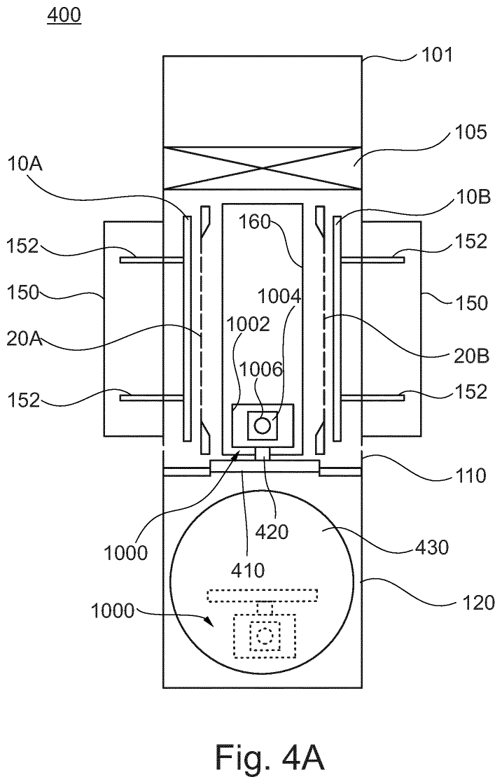

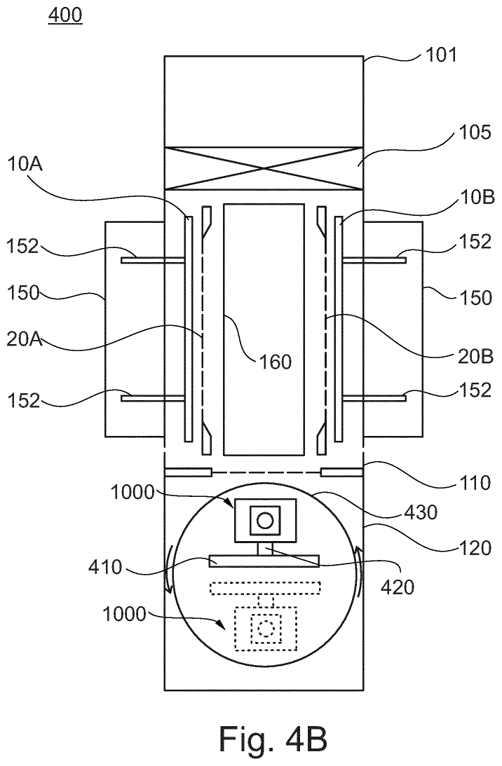

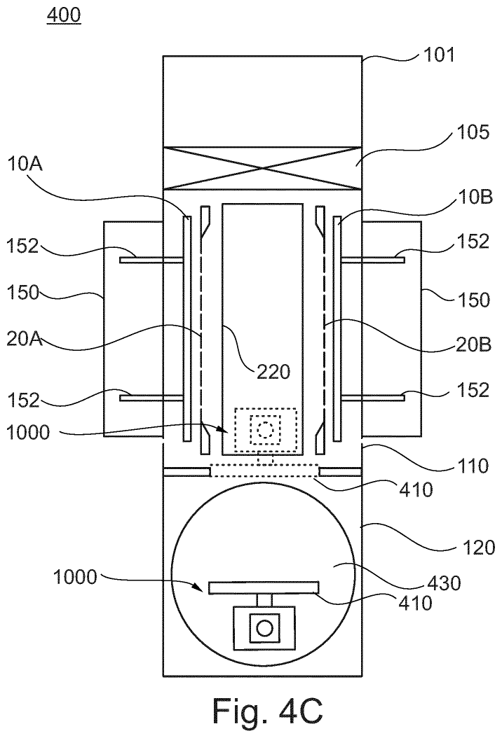

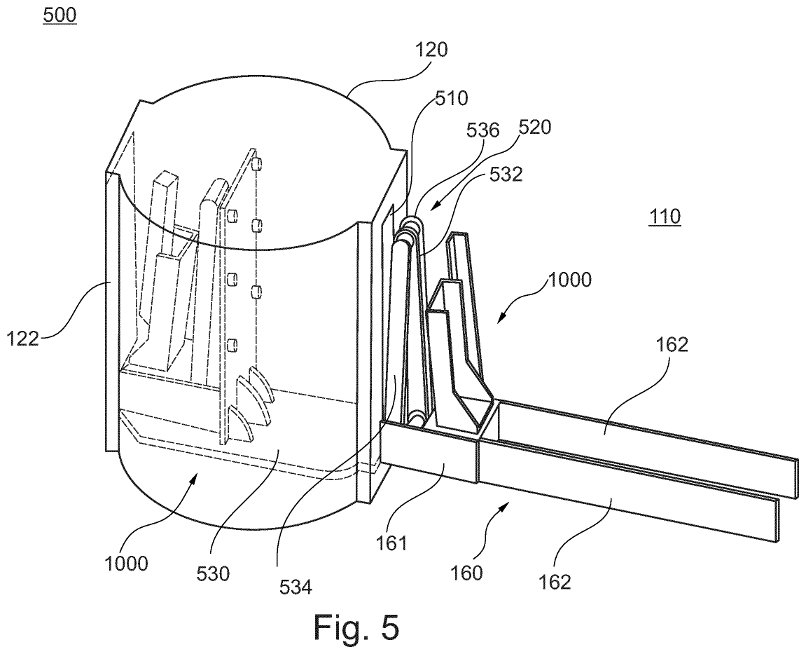

In some implementations, the maintenance vacuum chamber 120 is provided adjacent to the processing vacuum chamber 110, and the maintenance vacuum chamber 120 and the processing vacuum chamber 110 are connected. According to some embodiments, which can be combined with other embodiments described herein, the connection of the maintenance vacuum chamber 120 and the processing vacuum chamber 110 includes the opening 130, wherein the opening 130 is configured for the transfer of the portion of the material deposition source from the processing vacuum chamber 110 to the maintenance vacuum chamber 120 and from the maintenance vacuum chamber 120 to the processing vacuum chamber 110. In some embodiments, the apparatus 100 further includes the sealing device configured for closing the opening 130 using the magnetic closing arrangement. In particular, the sealing device can be configured for sealing the opening 130 substantially vacuum-tight. As an example, the sealing device is attached to the evaporation source 1000, as is explained with respect to FIGS. 4A to 4C and FIG. 5. When the opening 130 is magnetically closed or sealed, the maintenance vacuum chamber 120 can be vented and opened for maintenance of the material deposition source without breaking the vacuum in the processing vacuum chamber 110.

In some examples, the opening 130, the magnetic closing arrangement and the sealing device can be included in a valve connecting the processing vacuum chamber 110 and the maintenance vacuum chamber 120. The valve can be configured for opening and closing the vacuum seal between the processing vacuum chamber 110 and the maintenance vacuum chamber 120. The portion of the material deposition source can be transferred to the maintenance vacuum chamber 120 while the valve is in an open state, i.e., while the opening is open/uncovered. Thereafter, the valve can be magnetically closed to provide the vacuum seal between the processing vacuum chamber 110 and the maintenance vacuum chamber 120. When the valve is closed, the maintenance vacuum chamber 120 can be vented and opened for maintenance of the material deposition source without breaking the vacuum in the processing vacuum chamber 110.

In the present disclosure, a “vacuum processing chamber” is to be understood as a vacuum chamber or a vacuum deposition chamber. The term “vacuum”, as used herein, can be understood in the sense of a technical vacuum having a vacuum pressure of less than, for example, 10 mbar. The pressure in a vacuum chamber as described herein may be between 10⁻⁵ mbar and about 10⁻⁸ mbar, specifically between 10⁻⁵ mbar and 10⁻⁷ mbar, and more specifically between about 10⁻⁶ mbar and about 10⁻⁷ mbar. According to some embodiments, the pressure in the vacuum chamber may be considered to be either the partial pressure of the evaporated material within the vacuum chamber or the total pressure (which may approximately be the same when only the evaporated material is present as a component to be deposited in the vacuum chamber). In some embodiments, the total pressure in the vacuum chamber may range from about 10⁻⁴ mbar to about 10⁻⁷ mbar, especially in the case that a second component besides the evaporated material is present in the vacuum chamber (such as a gas or the like).

According to some embodiments, which can be combined with other embodiments described herein, the carriers are configured for holding or supporting the substrate and the mask in a substantially vertical orientation. As used throughout the present disclosure, “substantially vertical” is understood particularly when referring to the substrate orientation, to allow for a deviation from the vertical direction or orientation of ±20° or below, e.g. of ±10° or below. This deviation can be provided for example because a substrate support with some deviation from the vertical orientation might result in a more stable substrate position. Further, fewer particles reach the substrate surface when the substrate is tilted forward. Yet, the substrate orientation, e.g., during the vacuum deposition process, is considered substantially vertical, which is considered different from the horizontal substrate orientation, which may be considered as horizontal ±20° or below.

The term “vertical direction” or “vertical orientation” is understood to distinguish over “horizontal direction” or “horizontal orientation”. That is, the “vertical direction” or “vertical orientation” relates to a substantially vertical orientation e.g. of the carriers, wherein a deviation of a few degrees, e.g. up to 10° or even up to 15°, from an exact vertical direction or vertical orientation is still considered as a “substantially vertical direction” or a “substantially vertical orientation”. The vertical direction can be substantially parallel to the force of gravity.

The embodiments described herein can be utilized for evaporation on large area substrates, e.g., for OLED display manufacturing. Specifically, the substrates for which the structures and methods according to embodiments described herein are provided, are large area substrates. For instance, a large area substrate or carrier can be GEN 4.5, which corresponds to a surface area of about 0.67 m² (0.73×0.92 m), GEN 5, which corresponds to a surface area of about 1.4 m² (1.1 m×1.3 m), GEN 7.5, which corresponds to a surface area of about 4.29 m² (1.95 m×2.2 m), GEN 8.5, which corresponds to a surface area of about 5.7 m² (2.2 m×2.5 m), or even GEN 10, which corresponds to a surface area of about 8.7 m² (2.85 m×3.05 m). Even larger generations such as GEN 11 and GEN 12 and corresponding surface areas can similarly be implemented. Half sizes of the GEN generations may also be provided in OLED display manufacturing.

According to some embodiments, which can be combined with other embodiments described herein, the substrate thickness can be from 0.1 to 1.8 mm. The substrate thickness can be about 0.9 mm or below, such as 0.5 mm. The term “substrate” as used herein may particularly embrace substantially inflexible substrates, e.g., a wafer, slices of transparent crystal such as sapphire or the like, or a glass plate. However, the present disclosure is not limited thereto and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.9 mm or below, such as 0.5 mm or below, wherein the flexibility of the substantially inflexible substrate is small in comparison to the flexible substrates.

According to embodiments described herein, the substrate may be made of any material suitable for material deposition. For instance, the substrate may be made of a material selected from the group consisting of glass (for instance soda-lime glass, borosilicate glass, and the like), metal, polymer, ceramic, compound materials, carbon fiber materials or any other material or combination of materials which can be coated by a deposition process.

FIG. 1C shows a schematic top view of an apparatus 200 for vacuum processing of a substrate according to further embodiments described herein. The apparatus of FIG. 1C is similar to the apparatus described with respect to FIGS. 1A and B and only the differences are described in the following.

In the apparatus of FIG. 1C, the evaporation crucible 1004 and the distribution pipe 1006 of the evaporation source 1000 are transferred from the processing vacuum chamber 110 to the maintenance vacuum chamber 120 and from the maintenance vacuum chamber 120 to the processing vacuum chamber 110, wherein the support 1002 for the distribution pipe 1006 is not transferred from the processing vacuum chamber 110 to the maintenance vacuum chamber 120 and from the maintenance vacuum chamber 120 to the processing vacuum chamber 110. In other words, the support 1002 for the distribution pipe 1006 remains in the processing vacuum chamber 110, while the evaporation crucible 1004 and the distribution pipe 1006 of the evaporation source 1000 are transferred.

By leaving the support 1002 in the processing vacuum chamber 110, the portion of the material deposition source to be serviced and/or exchanged can be transferred to the maintenance vacuum chamber 120, wherein portions of the material deposition source which are not to be serviced and/or exchanged remain in the processing vacuum chamber 110. An effort for performing the transfer can be minimized.

FIG. 2 is a schematic illustration of subsequent stages (a), (b), (c) for closing the opening 215 between the processing vacuum chamber and the maintenance vacuum chamber.

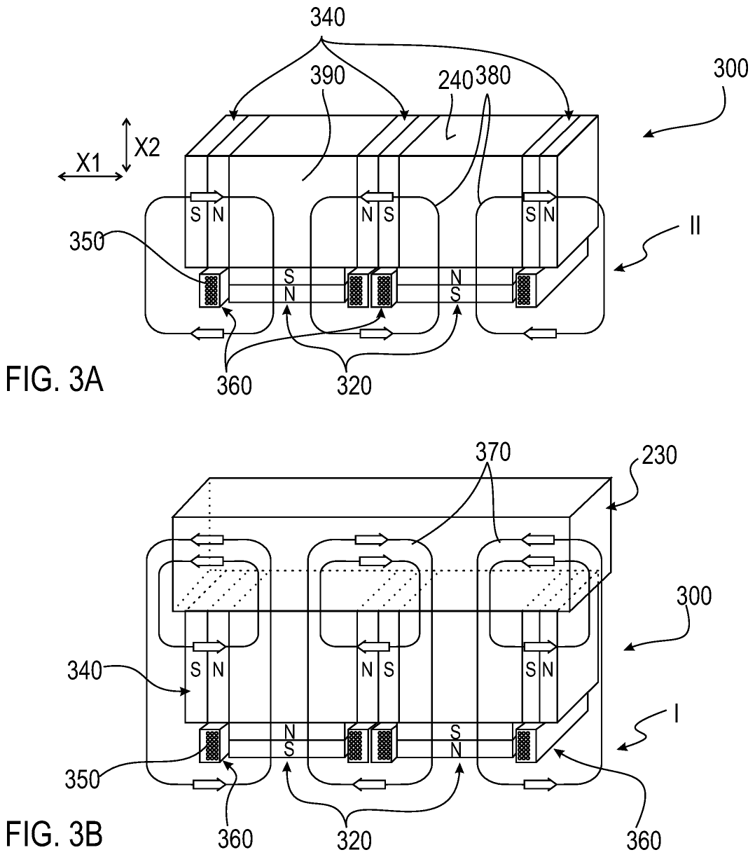

The apparatus for vacuum processing of a substrate according to the present disclosure includes the magnetic closing arrangement 220 for magnetically closing the opening 215 that is configured for transferring at least a portion of the material deposition source, e.g., the entire material deposition source, between the processing vacuum chamber and the maintenance vacuum chamber. “Magnetically closing” as used throughout the present disclosure can be understood in the sense that a magnetic force is used to seal the opening, e.g., essentially vacuum-tight. As an example, the sealing device 230 can be configured to cover the opening, wherein the magnetic closing arrangement 220 can be configured to hold the sealing device 230 at the opening 215 using a magnetic force. In some implementations, the magnetic closing arrangement 220 can include, or be, an electromagnet or an electropermanent magnet arrangement. The electropermanent magnet arrangement is further explained with respect to FIGS. 3A and B.

According to some embodiments, which can be combined with other embodiments described herein, the apparatus includes a partition 210 configured to separate the processing vacuum chamber and the maintenance vacuum chamber from each other. The partition 210 can be a chamber wall of the processing vacuum chamber and/or the maintenance vacuum chamber. The opening 215 can be provided in the partition 210.

In some implementations, at least a portion of the magnetic closing arrangement 220 can be provided at the opening 215. As an example, the magnetic closing arrangement 220 can be provided adjacent to the opening 215, e.g., at or in the partition 210. The magnetic closing arrangement 220 can be configured for attracting the sealing device 230 toward the opening 215, e.g., a holding surface 240.

According to some embodiments, the sealing device 230 can include, or be made of, a magnetic material. The magnetic field generated by the magnetic closing arrangement 220 can act on the magnetic material to provide the magnetic force attracting the sealing device 230 towards the opening 215, and particularly towards the holding surface 240. In some implementations, the magnetic material can be selected from the group consisting of iron, steel, stainless steel, a ferromagnetic material, a ferrimagnetic material, a diamagnetic material, and any combination thereof.

According to further embodiments, the sealing device 230 can include one or more magnet elements. The one or more magnet elements can be located corresponding to the magnetic closing arrangement 220 such that the magnetic field generated by the magnetic closing arrangement 220 can act on the one or more magnet elements to provide the magnetic force attracting the sealing device 230 towards the opening 215, and particularly towards the holding surface 240. The one or more magnet elements can be permanent magnets attached to, or integrated in, the sealing device 230. In such a case, the sealing device 230 can be made of a non-magnetic material, such as aluminum.

According to some embodiments, the apparatus includes the holding surface 240 at the opening 215. The holding surface 240 can be provided by the partition 210, e.g., adjacent the opening 215. As an example, the holding surface 240 can be configured to contact a surface of the sealing device 230. One or more sealing elements, such as O-rings, can be provided at the holding surface 240 such that the opening 215 can be sealed essentially vacuum-tight.

Turning now to FIG. 2, in a stage (a), the sealing device 230 is moved toward the opening 215, e.g., the holding surface 240. As an example, the sealing device can perform an essentially linear movement towards the opening 215. In some embodiments, which may be combined with other embodiments described herein, the magnetic closing arrangement 220 may be switchable between a chucking state I and a releasing state II. In the releasing state II, the magnetic closing arrangement 220 may generate no external magnetic field or a small external magnetic field at the holding surface 240. In the chucking state I, the magnetic closing arrangement 220 may generate a strong external magnetic field at the holding surface 240. In other words, a second external magnetic field at the holding surface 240 in the releasing state II may be smaller than a first external magnetic field at the holding surface 240 in the chucking state I.

The first external magnetic field may be sufficient to hold the sealing device 230 at the opening 215. In some implementations, the magnetic closing arrangement 220 can be configured to provide a force of 10 N/cm² or more, specifically 50 N/cm² or more, specifically 100 N/cm² or more, and more specifically 150 N/cm² or more. The force can be the magnetic force acting on the sealing device to hold the sealing device 230 at the opening 215, and particularly at the holding surface 240.

In stage (a) of FIG. 2, the magnetic closing arrangement 220 is provided in the releasing state II in which the magnetic closing arrangement 220 may generate no external magnetic field or only a small external magnetic field at the holding surface 240. Accordingly, the sealing device 230 is not attracted toward the holding surface 240.

In stage (b) of FIG. 2, the sealing device 230 has moved to be in contact with the partition 210. The magnetic closing arrangement 220 is still in the releasing state II in which the sealing device 230 is not held at the holding surface 240 by a magnetic force of the magnetic closing arrangement 220.

In stage (c) of FIG. 2, the magnetic closing arrangement 220 has switched to the chucking state I. In the chucking state I, the magnetic field generated by the magnetic closing arrangement 220 holds the sealing device 230 at the holding surface 240. The processing vacuum chamber and the maintenance vacuum chamber can be sealed from each other essentially vacuum-tight.

Similarly, the sealing device 230 can be detached e.g. from the partition 210 by switching the magnetic closing arrangement 220 from the chucking state I to the releasing state II in which no external magnetic field or only a small external magnetic field is generated at the holding surface 240, as is depicted in stage (b) of FIG. 2. The sealing device 230 can then be removed from the opening 215 such that the material deposition source or the portion of the material deposition source can be moved through the opening 215.

The magnetic closing arrangement 220 may be switched between the releasing state I and the chucking state II by changing a direction of magnetization of one or more first permanent magnets of the magnetic closing arrangement 220, e.g. by an electric pulse provided to a magnet device of the magnetic closing arrangement 220. In particular, a polarity of the one or more first permanent magnets may be reversed by an electric pulse sent to the magnet device. In some embodiments, the apparatus includes a power supply 250 for the magnetic closing arrangement 220. The power supply 250 can be configured to generate an electric pulse, e.g. a current pulse, which may be suitable for changing the magnetization of the one or more first permanent magnets. This is further explained with respect to FIGS. 4A and B.

FIG. 4A is a schematic view of a magnetic closing arrangement 300 according to embodiments described herein in a releasing state II. FIG. 4B is a schematic view of the magnetic closing arrangement 300 of FIG. 4A in a chucking state I in which a device, e.g. the sealing device 230, is held by the magnetic closing arrangement 300.

The magnetic closing arrangement 300 may be configured as an electropermanent magnet arrangement. An electropermanent magnet arrangement includes one or more first permanent magnets 320, one or more second permanent magnets 340, and a magnet device 360. The electropermanent magnet arrangement uses two magnetic planes that are oriented with respect to each other under an angle of about 90°.

In more detail, an electropermanent magnet arrangement (or “EPM”) as used herein may be understood as a magnet arrangement in which a magnetic field generated by permanent magnets can be changed by an electric pulse, particularly by a current pulse in a winding of the magnet device 360. In particular, the magnetic field may be switched on or off on one side of the magnetic closing arrangement 300 where the holding surface 240 is provided. Electropermanent magnets may work based on the double magnet principle. The one or more first permanent magnets 320 may consist of a “soft” or “semi-hard” magnetic material, i.e. a material with a low coercivity. The one or more second permanent magnets 340 may consist of a “hard” magnetic material, i.e. a material with a higher coercivity. The direction of magnetization of the one or more first permanent magnets 320 can be changed by an electric pulse provided to the magnet device 360. As an example, a polarity of the one or more first permanent magnets 320 can be reversible by the electric pulse. The direction of magnetization of the one or more second permanent magnets 340 may remain constant due to the high coercivity of the respective material.

The polarity of the one or more first permanent magnets 320 and the polarity of the one or more second permanent magnets 340 are magnetic polarities, i.e., magnetic south poles and magnetic north poles.

According to some embodiments, a duration of the electric pulse to change the magnetization of the one or more first permanent magnets 320 is 0.1 s or more, specifically is or more, and more specifically 3 s or more. As an example, the duration of the electric pulse is in a range between 0.1 and 10 s, specifically in a range between 0.5 and 5 s, and more specifically in a range between 1 and 2 s.

In some embodiments, the magnet device 360 may include a winding 350, e.g. a wire winding or solenoid that is provided at least partially around the one or more first permanent magnets 320. By supplying an electric pulse through the winding 350, a local magnetic field at the position of the one or more first permanent magnets 320 is generated which changes the magnetization of the one or more first permanent magnets 320. In particular, a polarity of the one or more first permanent magnets 320 may be reversed by feeding a current pulse through the winding 350 of the magnet device 360.

In some embodiments, a plurality of first permanent magnets is provided, wherein the first permanent magnets are at least partially surrounded by windings of the magnet device 360. For example, in the embodiment of FIG. 4A, two first permanent magnets are depicted, wherein a wire winding extends around each of the two first permanent magnets. More than two first permanent magnets may be arranged next to each other. In some embodiments, the polarities of two adjacent first permanent magnets directed toward the holding surface 240 may be opposite polarities, respectively. Accordingly, the magnetic field lines may form one or more loops wherein each loop penetrates through adjacent first permanent magnets in opposite directions.

In some embodiments, a plurality of second permanent magnets is provided. For example, in the embodiment of FIG. 4A, three second permanent magnets are depicted. Two, three or more second permanent magnets may be provided, e.g. one after the other in a row arrangement. The second permanent magnets may be arranged such that poles of opposite polarities of adjacent second permanent magnets may be directed toward each other. Accordingly, the magnetic field lines do not linearly extend through the row of second permanent magnets but a plurality of separate loops may form due to the opposite poles facing each other.

In some embodiments, the one or more first permanent magnets 320 may be arranged in a first plane, and the one or more second permanent magnets 340 may be arranged in a second plane. The second plane may be closer to the holding surface 240 than the first plane. Accordingly, the one or more second permanent magnets 340 may be arranged closer to the holding surface 240 than the one or more first permanent magnets 320.

In some embodiments, the one or more first permanent magnets 320 may have a first orientation and the one or more second permanent magnets 340 may have a second orientation different from the first orientation. In particular, the first orientation and the second orientation may be perpendicular. For example, the one or more first permanent magnets 320 may be oriented in a horizontal direction or plane and the one or more second permanent magnets 340 may be oriented in a vertical orientation or plane.

In some embodiments, the magnetic field generated by the one or more second permanent magnets 340 may have a first main orientation X1 which can be essentially parallel to the holding surface 240. The magnetic field generated by the one or more first permanent magnets 320 may have a second main orientation X2 which can be essentially perpendicular to the holding surface 240. Accordingly, by reversing the polarities of the one or more first permanent magnets 320, the resultant total magnetic field may change in a direction perpendicular to the holding surface 240, i.e. toward an interior of the sealing device 230 or toward an exterior of the sealing device 230. By switching the magnetic closing arrangement 300 from the releasing state II of FIG. 4A to the chucking state I of FIG. 4B, the resultant overall magnetic field can be shifted to an exterior of the holding surface 240 such as to penetrate into a device to be attached. In particular, in the chucking state I, opposite poles of the one or more first permanent magnets 320 and of the one or more second permanent magnets 340 may be facing each other such that the magnetic field lines may be urged toward an outer environment of the holding surface 240 where the device to be attached is arranged.

The external magnetic field 370 which penetrates into the sealing device 230 is schematically depicted in FIG. 4B. The external magnetic field 370 remains in the sealing device 230 until the polarity of the one or more first permanent magnets 320 is reversed by an electric pulse. The chucked sealing device can be released by providing an electric pulse to the magnet device 360. A reliable attachment of the sealing device 230 can be obtained also in case of a power failure, because the sealing device 230 is held by a magnetic force generated by permanent magnets. In the chucking state I, no external power may be needed for maintaining the chucked state. No heat due to continuously operating electric devices is generated and an additional cooling is not needed to maintain process stability. A bistable magnet arrangement can be provided which remains in the releasing state II or in the chucking state I after switching. The switching can be performed automatically.

The internal magnetic field 380 that is generated by the magnetic closing arrangement 300 in the releasing state II is schematically depicted in FIG. 4A. A core 390 such as a steel core may be provided for increasing the magnetic field strength, e.g. between adjacent second permanent magnets, respectively.

In some embodiments, which may be combined with other embodiments described herein, the one or more first permanent magnets 320 include a soft or semi-hard magnetic material, and/or the one or more second permanent magnets 340 include a hard magnetic material. For example, the one or more first permanent magnets 320 may include AlNiCo and/or the one or more second permanent magnets 340 may include neodymium. In particular, the one or more first permanent magnets 320 may be AlNiCo-magnets, and/or the one or more second permanent magnets 340 may be neodymium-magnets. Other magnets with low and high coercivities may be used. For example, the hard magnetic material may have a coercivity of 1.000 kA/m or more, particularly 10.000 kA/m or more, and/or the soft magnetic material may have a coercivity of 1.000 kA/m or less, particularly 100 kA/m or less.

FIGS. 4A to 4C show schematic top views of an apparatus 400 for vacuum processing of a substrate according to further embodiments described herein. The apparatus 400 of FIGS. 4A to C is similar to the apparatuses described above and only the differences are described in the following.

According to some embodiments, which can be combined with other embodiments described herein, the connection of the maintenance vacuum chamber 120 and the processing vacuum chamber 110 includes the opening, wherein the opening is configured for the transfer of at least a portion of the material deposition source, e.g., the evaporation source 1000, from the processing vacuum chamber 110 to the maintenance vacuum chamber 120 and from the maintenance vacuum chamber 120 to the processing vacuum chamber 110.

In some embodiments, the apparatus 400 further includes the sealing device 410 configured for closing the opening. In particular, the sealing device 410 is configured for sealing the opening substantially vacuum-tight. When the opening is closed or sealed by the sealing device 410, the maintenance vacuum chamber 120 can be vented and opened for maintenance of the evaporation source 1000 without breaking the vacuum in the processing vacuum chamber 110.

In some implementations, the sealing device 410 is attached to, or included in, the evaporation source 1000. As an example, the sealing device 410 can be mounted to a side of the evaporation source 1000, e.g., at the support 1002, in a substantially vertical orientation. In some embodiments, the sealing device 410 can be a plate that is configured for sealing or closing the opening between the processing vacuum chamber 110 and the maintenance vacuum chamber 120. Integrating the sealing device 410 with the evaporation source 1000 allows for saving space within the processing vacuum chamber 110 and/or the maintenance vacuum chamber 120.

According to some embodiments, the evaporation source 1000 is moveable with respect to the sealing device 410. As an example, at least the distribution pipe 1006 and the evaporation crucible 1004 are moveable with respect to the sealing device 410. In some implementations, the apparatus 400 can include a connection device 420 connecting the evaporation source 1000 and the sealing device 410. The connection device 420 can be configured to provide the moveable connection between the evaporation source 1000 and the sealing device 410. As an example, the sealing device 410 can include two or more arm portions connected by hinges, in order to provide the moveable connection.

In some implementations, the connection device 420 can be a translation device configured for moving the sealing device 410 with respect to the evaporation source 1000, and in particular with respect to the distribution pipe 1006 and the evaporation crucible 1004. For closing the opening, the evaporation source 1000 can be suitably positioned within the processing vacuum chamber 110 or the maintenance vacuum chamber 120, and the translation device can move the sealing device 410 with respect to the evaporation source 1000 towards the opening in order to close or seal the opening substantially vacuum-tight. The sealing device 410 can be fixed with respect to the evaporation source 1000 during transfer from the maintenance vacuum chamber 120 to the processing vacuum chamber 110 and vice versa.

According to some embodiments, which can be combined with other embodiments described herein, the apparatus 400 includes a rotatable device 430 provided in the maintenance vacuum chamber 120. The rotatable device 430 can be configured for receiving the evaporation source 1000. As an example, the rotatable device 430 can be a rotatable platform.

Referring to FIG. 4A, two evaporation sources 1000 are shown. A first evaporation source of the two evaporation sources is positioned in the processing vacuum chamber 110, and a second evaporation source of the two evaporation sources is positioned in the maintenance vacuum chamber 120. As an example, the second evaporation source of the two evaporation sources can be positioned on the rotatable device 430.

As shown in FIG. 4B, the first evaporation source, e.g., to be serviced or exchanged, can be transferred from the processing vacuum chamber 110 to the maintenance vacuum chamber 120, and in particular onto the rotatable device 430. For example, the first evaporation source and the second evaporation source can be positioned back-to-back on the rotatable device 430, e.g., with the sealing devices being oriented towards each other. In other words, both sealing devices can be positioned or sandwiched between the first evaporation source and the second evaporation source.

When both evaporations sources, i.e., the first evaporation source and the second evaporation source, are positioned on the rotatable device 430, the rotatable device 430 is rotated, e.g., about 180 degrees, so that the first evaporation source and the second evaporation source exchange positions. In FIG. 4B, the rotation is indicated with arrows. Then, the second evaporation source can be transferred into the processing vacuum chamber 110 and the opening connecting the processing vacuum chamber 110 and the maintenance vacuum chamber 120 can be sealed, e.g., by the sealing device 410 of the second evaporation source. The maintenance vacuum chamber 120 can be vented for servicing or removal of the first evaporation source. This allows an exchange of evaporation sources without having to break the vacuum in the processing vacuum chamber 110.

FIG. 5 shows a schematic top view of an apparatus 500 for vacuum processing of a substrate according to embodiments described herein. The apparatus 500 of FIG. 5 is similar to the apparatus described above with reference to FIGS. 4A to C, and only the differences are described in the following.

According to some embodiments, which can be combined with other embodiments described herein, the apparatus 500 includes the evaporation source support system disposed in the processing vacuum chamber 110 and having the at least two tracks 160, wherein the at least two tracks 160 of the evaporation source support system are configured for the movement of the evaporation source 1000 at least within the processing vacuum chamber 110. Each one of the at least two tracks 160 includes a first track section 161 and a second track section 162, wherein the first track section 161 and the second track section 162 are separable. In some implementations, the first track section 161 is configured to be transferable from the processing vacuum chamber 110 to the maintenance vacuum chamber 120 and from the maintenance vacuum chamber 120 to the processing vacuum chamber 110 together with the evaporation source 1000.

According to some embodiments, the evaporation source 1000 is moveable with respect to the sealing device 510. As an example, the apparatus 500 can include a connection device 520 connecting the evaporation source 1000 and the sealing device 510. As an example, the connection device 520 is configured for guiding the translational movement of the sealing device 510 with respect to the evaporation source 1000. Additionally or alternatively, the connection device 520 can provide or accommodate a media supply for the evaporation source 1000. As an example, the connection device 520 can be an arm, in particular a passive arm. In some embodiments, at least a portion of the connection device 520 provides an atmospheric environment to prevent any particle impact on the media supply. As an example, the atmospheric environment can be provided inside the connection device 520, and can in particular be provided inside of the arm.

In some implementations, the arm can include two or more arm portions connected by respective hinges to allow the relative movement between the evaporation source 1000 and the sealing device 510. As an example, the connection device 520 includes a first arm 532 and a second arm 534. The first arm 532 has a first end portion connected to the evaporation source 1000 and a second end portion connected to a third end portion of the second arm 534 via a hinge 536. The second arm 534 has a fourth end portion connected to the processing vacuum chamber 110 and/or the maintenance vacuum chamber 120.

According to some embodiments, which can be combined with other embodiments described herein, the apparatus 500 includes a rotatable device 530 provided within the maintenance vacuum chamber 120. The rotatable device 530 can be configured for receiving the evaporation source 1000 and/or the first track sections 161. As an example, the rotatable device 530 can be a rotatable platform. In some embodiments, the apparatus 500 includes a drive configured for driving or rotating the rotatable device 530. The drive may be connected to the rotatable device 530 via a shaft, e.g., a hollow shaft.

According to some embodiments, the rotatable device 530 is configured for supporting two or more evaporation sources. As an example, a first evaporation source, e.g., to be serviced or exchanged, can be transferred from the processing vacuum chamber 110 to the maintenance vacuum chamber 120, and in particular onto the rotatable device 530. A second evaporation source, e.g., a serviced or new one, can also be provided on the rotatable device 530. When both evaporation sources, i.e., the first evaporation source and the second evaporation source, are positioned on the rotatable device 530, the rotatable device 530 is rotated, e.g., about 180 degrees, so that the first evaporation source and the second evaporation source exchange positions. Then, the second evaporation source can be transferred into the processing vacuum chamber 110 and the opening connecting the processing vacuum chamber 110 and the maintenance vacuum chamber 120 can be magnetically sealed, e.g., using the sealing device 510 and the magnetic closing arrangement. The maintenance vacuum chamber 120 can be vented for servicing or removal of the first evaporation source, e.g., by opening a door 122 of the maintenance vacuum chamber 120. This allows for an exchange of evaporation sources without having to break the vacuum in the processing vacuum chamber 110.

According to some embodiments, which can be combined with other embodiments described herein, the apparatus 500 can include a supply passage, e.g., a supply line. The supply passage can be configured for supplying the evaporation source 1000, e.g., with electrical connections and/or media such as fluids (e.g., water) and/or gases. The supply passage may be configured for guiding one or more lines and/or cables therethrough, such as water supply lines, gas supply lines and/or electric cables. In some implementations, the supply passage has an atmospheric environment, i.e. the supply passage can be configured to maintain atmospheric pressure therein even when a surrounding such as the processing vacuum chamber 110 and/or the maintenance vacuum chamber 120 is evacuated to a technical vacuum. As an example, the supply passage can include at least a part of the connection device 520.

In some implementations, the supply passage extends from the evaporation source 1000 to a feed through provided between the processing vacuum chamber 110 and the maintenance vacuum chamber 120. As an example, the feed through can be provided in or at the sealing device 510 or a wall portion separating the processing vacuum chamber 110 and the maintenance vacuum chamber 120. According to some embodiments, the supply passage extends from the evaporation source 1000 to the feed through via at least one of the evaporator control housings (that can be the atmospheric box) and the connection device 520.

In some embodiments, the supply passage extends from an outside of the maintenance vacuum chamber 120 into the maintenance vacuum chamber, e.g., through a hollow shaft of the drive of the rotatable device 530, and into an intermediate space or bottom of the rotatable device 530. The supply passage can further extend from the intermediate space or bottom of the rotatable device 530, e.g., via a pipe such as corrugated hose, to an atmospheric box provided in or at the sealing device 510. An atmospheric box can be included in a “back pack” attached to the sealing device 510. The above-mentioned feed through can be provided in or at the atmospheric box provided in or at the sealing device 510. As an example, the atmospheric box provided in or at the sealing device 510 can be configured as the feed-through. The supply passage can further extend from the atmospheric box provided in or at the sealing device 510 to the evaporator control housing via the connection device 520. The supply passage can then extend from the evaporator control housing to the evaporation source 1000, e.g., to an atmospheric box of the evaporation source 1000, through a hollow shaft of the actuator configured to rotate at least the distribution pipes 1006.

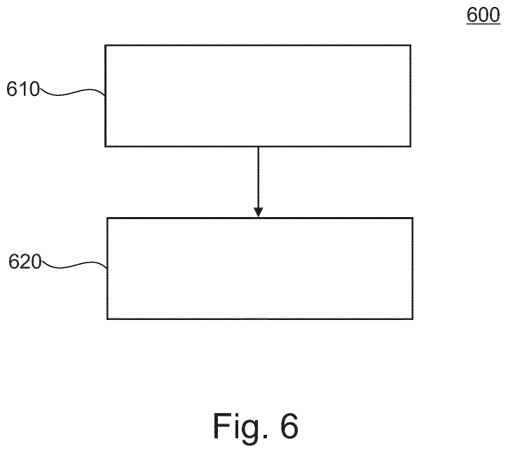

FIG. 6 shows a flowchart of a method 600 for sealing a processing vacuum chamber and a maintenance vacuum chamber from each other according to embodiments described herein. The method 600 can be implemented using the apparatuses and systems described herein.

The method 600 includes, in block 610, holding a sealing device at an opening using a magnetic force. The opening can connect the processing vacuum chamber and the maintenance vacuum chamber such that at least a portion of a material deposition source, such as an evaporation source, can be transferred between the processing vacuum chamber and the maintenance vacuum chamber. In some implementations, the method 600 further includes, in block 620, a releasing of the sealing device from the opening by changing the magnetic force. For example, changing the magnetic force can include a reversing of a polarity of one or more first permanent magnets using, for example, an electric pulse.

According to embodiments described herein, the method for sealing a processing vacuum chamber and a maintenance vacuum chamber from each other can be conducted using computer programs, software, computer software products and the interrelated controllers, which can have a CPU, a memory, a user interface, and input and output devices being in communication with the corresponding components of the apparatus.

The embodiments disclosed herein facilitate servicing and/or refilling of material deposition sources, such as evaporation sources, and can reduce a downtime of the processing apparatus. In particular, the maintenance vacuum chamber is connected to the processing vacuum chamber such that at least a portion of the material deposition source can be transferred from the processing vacuum chamber to the maintenance vacuum chamber, and vice versa, via a sealable opening. The maintenance vacuum chamber can be vented independently from the processing vacuum chamber. The material deposition source can be exchanged, e.g., after the material deposition source is exhausted, and/or serviced in the maintenance vacuum chamber without venting the vacuum system and/or without stopping production.

The sealable opening is closable using a magnetic closing arrangement. For example, a sealing device, such as a service flange, can cover the opening and can be magnetically held at the opening to seal the opening. The magnetic sealing can reduce a number of mechanically movable parts in the vacuum system. A generation of particles due to such mechanically movable parts can be reduced and a quality of the material layers deposited on the substrate can be improved.

While the foregoing is directed to embodiments of the disclosure, other and further embodiments of the disclosure may be devised without departing from the basic scope thereof, and the scope thereof is determined by the claims that follow.

1. An apparatus for vacuum processing of a substrate, comprising:
a processing vacuum chamber and a maintenance vacuum chamber;
an opening for transferring at least a portion of a material deposition source between the processing vacuum chamber and the maintenance vacuum chamber; and
a magnetic closing arrangement for magnetically closing the opening.

2. The apparatus of claim 1, further including a sealing device configured for closing the opening.

3. The apparatus of claim 2, wherein the sealing device is attached to the material deposition source.

4. The apparatus of claim 1, wherein the magnetic closing arrangement includes:
one or more first permanent magnets;
one or more second permanent magnets; and
a magnet device configured to change a magnetization of the one or more first permanent magnets.

5. The apparatus of claim 4, wherein the one or more first permanent magnets include a soft magnetic material or a semi-hard magnetic material, and wherein the one or more second permanent magnets include a hard magnetic material.

6. The apparatus of claim 4, wherein the magnet device includes a winding provided at least partially around the one or more first permanent magnets.

7. The apparatus of claim 4, wherein a direction of a magnetization of the one or more first permanent magnets is switchable by an electric pulse provided to the magnet device, wherein a polarity of the one or more first permanent magnets is reversible by the electric pulse.

8. The apparatus of claim 1, wherein the magnetic closing arrangement is provided at the opening.

9. The apparatus of claim 1, further including a holding surface at the opening, wherein the magnetic closing arrangement is switchable between a chucking state and a releasing state, wherein, in the chucking state, the magnetic closing arrangement generates a first external magnetic field at the holding surface, and wherein, in the releasing state, the magnetic closing arrangement generates no external magnetic field or a second external magnetic field smaller than the first external magnetic field at the holding surface.

10. The apparatus of claim 1, wherein the portion of the material deposition source includes at least one of an evaporation crucible and a distribution pipe, and wherein the material deposition source further includes a support for the distribution pipe.

11. The apparatus of claim 10, wherein the evaporation crucible and the distribution pipe of the evaporation source can be transferred from the processing vacuum chamber to the maintenance vacuum chamber and from the maintenance vacuum chamber to the processing vacuum chamber, and wherein the support for the distribution pipe is not transferred from the processing vacuum chamber to the maintenance vacuum chamber and from the maintenance vacuum chamber to the processing vacuum chamber.

12. A system for the manufacture of devices having organic materials, comprising:
a processing vacuum chamber and a maintenance vacuum chamber having an opening for transferring at least a portion of a material deposition source between the processing vacuum chamber and the maintenance vacuum chamber;
a magnetic closing arrangement for magnetically closing the opening; and
a transport arrangement configured for contactless transportation of at least one of a substrate carrier and a mask carrier in the processing vacuum chamber.

13. A method for sealing a processing vacuum chamber and a maintenance vacuum chamber from each other, comprising:
holding a sealing device at an opening using a magnetic force.

14. The method of claim 13, further including:
releasing the sealing device from the opening by changing the magnetic force.

15. The method of claim 14, wherein changing the magnetic force includes:
reversing a polarity of one or more first permanent magnets.

16. The apparatus of claim 2, wherein the magnetic closing arrangement includes:
one or more first permanent magnets;
one or more second permanent magnets; and
a magnet device configured to change a magnetization of the one or more first permanent magnets.

17. The apparatus of claim 3, wherein the magnetic closing arrangement includes:
one or more first permanent magnets;
one or more second permanent magnets; and
a magnet device configured to change a magnetization of the one or more first permanent magnets.

18. The apparatus of claim 5, wherein the magnet device includes a winding provided at least partially around the one or more first permanent magnets.

19. The apparatus of claim 5, wherein a direction of a magnetization of the one or more first permanent magnets is switchable by an electric pulse provided to the magnet device, wherein a polarity of the one or more first permanent magnets is reversible by the electric pulse.

20. The apparatus of claim 4, further including a holding surface at the opening, wherein the magnetic closing arrangement is switchable between a chucking state and a releasing state, wherein, in the chucking state, the magnetic closing arrangement generates a first external magnetic field at the holding surface, and wherein, in the releasing state, the magnetic closing arrangement generates no external magnetic field or a second external magnetic field smaller than the first external magnetic field at the holding surface.
